(19) United States
(12) Patent Application Publication
(10) Pub. No.: US 2025/0093777 A1
(43) Pub. Date: Mar. 20, 2025

(54) RESIST UNDERLAYER COMPOSITION AND METHOD OF FORMING PATTERNS USING THE COMPOSITION

(71) Applicant: SAMSUNG SDI CO., LTD., Yongin-si (KR)

(72) Inventors: Byeonggyu HWANG, Suwon-si (KR); Changmo LIM, Suwon-si (KR); Jaeyeol BAEK, Suwon-si (KR); Soonhyung KWON, Suwon-si (KR); Hwayoung JIN, Suwon-si (KR); Soojeung KIM, Suwon-si (KR); Eunsu LEE, Suwon-si (KR); Seongjin KIM, Suwon-si (KR); Ahra CHO, Suwon-si (KR); Yoojeong CHOI, Suwon-si (KR); Sungwoo JUNG, Suwon-si (KR)

(21) Appl. No.: 18/890,487

(22) Filed: Sep. 19, 2024

(30) Foreign Application Priority Data
Sep. 20, 2023 (KR) 10-2023-0125740

(51) Int. Cl. G03F 7/039; G03F 7/004; G03F 7/038

(52) U.S. Cl. CPC G03F 7/0397; G03F 7/0048; G03F 7/0382; G03F 7/0387

(57) ABSTRACT

Disclosed are a resist underlayer composition, and a method of forming a pattern using the resist underlayer composition. the resist underlayer composition includes a polymer including a structural unit represented by Chemical Formula 1, a structural unit represented by Chemical Formula 2, a structural unit represented by Chemical Formula 3, or a combination thereof and a solvent. The definitions of Chemical Formula 1 to Chemical Formula 3 are as described in the specification.

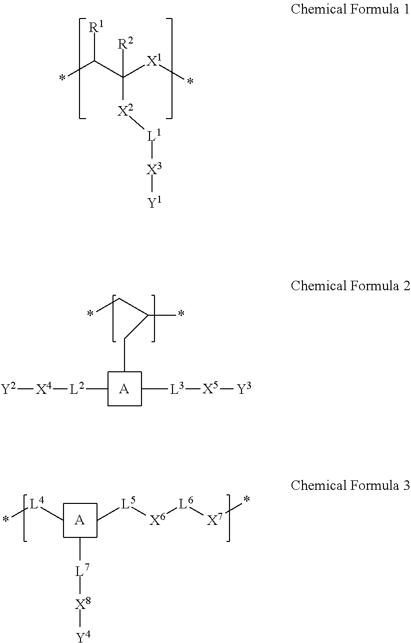

### CROSS-REFERENCE TO RELATED APPLICATION

This application claims priority to and the benefit of Korean Patent Application No. 10-2023-0125740 filed in the Korean Intellectual Property Office on Sep. 20, 2023, the entire content of which is hereby incorporated by reference.

### BACKGROUND

### 1. Field

Embodiments of this disclosure relate to a resist underlayer composition, and a method of forming patterns using the same.

### 2. Description of the Related Art

Recently, a semiconductor industry has developed an ultra-fine technique having a pattern of several to several tens of nanometers in size. To realize these ultra-fine technologies, effective lithographic techniques are beneficial.

The lithographic technique is a processing method that involves coating a photoresist layer on a semiconductor substrate such as, for example, a silicon wafer to form a thin film, irradiating activating radiation such as, for example, ultraviolet rays through a mask pattern on which the device pattern is drawn, developing it to obtain a photoresist pattern, and etching the substrate using the obtained photoresist pattern as a protective film to form a fine pattern corresponding to the pattern on the surface of the substrate.

As semiconductor patterns become increasingly finer, a thickness of the photoresist layer should be thin, and accordingly, a thickness of the resist underlayer should also be thin. The resist underlayer should keep the photoresist pattern despite the thinness, for example, should have a substantially uniform thickness as well as excellent or suitable close contacting property and adherence to the photoresist. The resist underlayer should not collapse the photoresist pattern even if it is thin, should have good adhesion to the photoresist, and should be formed to have a uniform (or substantially uniform) thickness. The resist underlayer should have a high refractive index and low extinction coefficient for the light used in photolithography and a faster etch rate than the photoresist layer.

### SUMMARY

The resist underlayer composition according to some embodiments of the present disclosure provides a resist underlayer that does not cause resist pattern collapse even in a fine patterning process and has improved sensitivity to an exposure light source, thereby improving patterning performance and energy efficiency.

Some embodiments provide a method of forming a pattern using the resist underlayer composition.

A resist underlayer composition according to some embodiments includes a polymer including a structural unit represented by Chemical Formula 1, a structural unit represented by Chemical Formula 2, a structural unit represented by Chemical Formula 3, or a combination thereof, and a solvent:

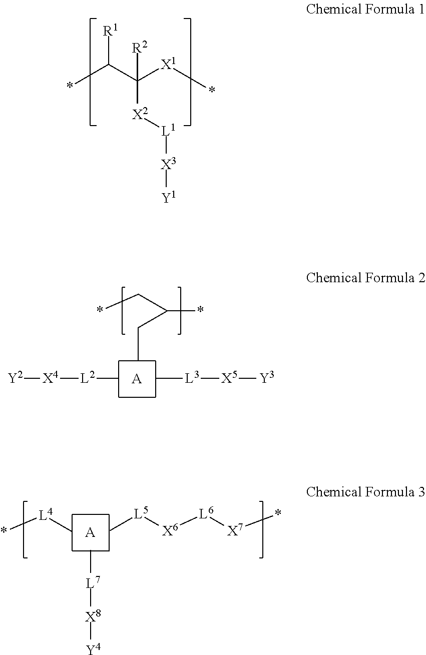

wherein, in Chemical Formula 1 to Chemical Formula 3,
R¹ and R² are each independently hydrogen, deuterium, a hydroxy group, a halogen atom, a substituted or unsubstituted C1 to C20 alkyl group, substituted or unsubstituted C2 to C20 alkenyl group, a substituted or unsubstituted C2 to C20 alkynyl group, or a combination thereof,
A is a heterocyclic group including a nitrogen atom in a ring,
L¹ to L⁷ are each independently a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C3 to C20 heterocycloalkylene group, a substituted or unsubstituted C6 to C20 arylene group, or a combination thereof,
X¹ to X⁸ are each independently a single bond (e.g., a single covalent bond), —O—, —S—, —S(═O)—, —S(═O)₂—, —C(═O)—, —(CO)O—, —O(CO)O—, —C(═O)NH—, —NR^{a}— (wherein, R^{a} is hydrogen, deuterium, or a C1 to C10 alkyl group), or a combination thereof,
Y¹ and Y⁴ are each a group represented by Chemical Formula 4,
Y² and Y³ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C3 to C20 heterocycloalkyl group, a substituted or unsubstituted C6 to C20 aryl group, a group represented by Chemical Formula 4, or a combination thereof, and one or more selected from Y² and Y³ is represented by Chemical Formula 4, and
* is a linking point:

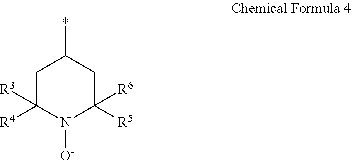

wherein, in Chemical Formula 4,
R³ to R⁶ are each independently hydrogen, deuterium, a substituted or unsubstituted C1 to C10 alkyl group, substituted or unsubstituted C2 to C10 alkenyl group, a substituted or unsubstituted C2 to C10 alkynyl group, or a combination thereof, and
* is a linking point.
R¹ and R² may each independently be hydrogen, or a substituted or unsubstituted C1 to C20 alkyl group, A may be a moiety represented by Chemical Formula A-1, L¹ to L⁷ may each independently be a single bond (e.g., a single covalent bond), or a substituted or unsubstituted C1 to C10 alkylene group, R¹ and R² may each independently be hydrogen, deuterium, a substituted or unsubstituted C1 to C10 alkyl group, or a combination thereof, and X¹ to X⁸ may each independently be a single bond (e.g., a single covalent bond), —O—, —C(═O)—, —(CO)O—, —C(═O)NH—, or a combination thereof.

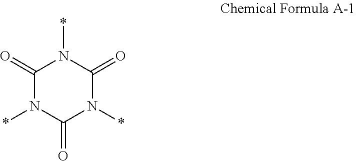 [SMILES: *n1c(=O)n(*)c(=O)n(*)c1=O]

In Chemical Formula A-1, * is a linking point.

R³ to R⁶ of Chemical Formula 4 are each independently hydrogen, deuterium, a substituted or unsubstituted C1 to C10 alkyl group, or a combination thereof.

The polymer may further include a structural unit represented by Chemical Formula 5, a structural unit represented by Chemical Formula 6, a structural unit represented by Chemical Formula 7, or a combination thereof:

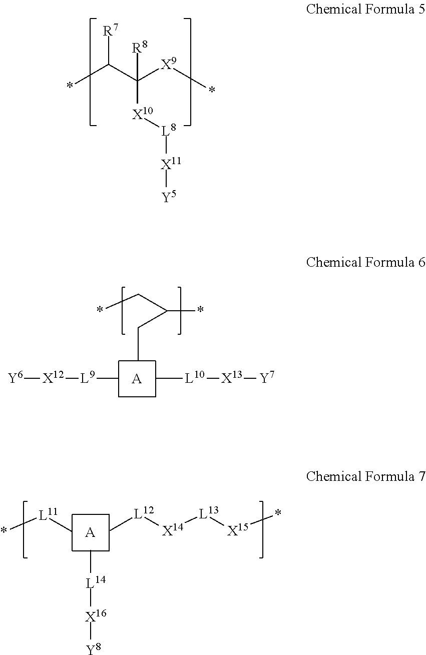

wherein, in Chemical Formula 5 to Chemical Formula 7,
R⁷ and R⁸ are each independently hydrogen, deuterium, a hydroxy group, a halogen atom, a substituted or unsubstituted C1 to C20 alkyl group, substituted or unsubstituted C2 to C20 alkenyl group, a substituted or unsubstituted C2 to C20 alkynyl group, or a combination thereof,
A is a heterocyclic group including a nitrogen atom in a ring,
L⁸ to L¹⁴ are each independently a single bond (e.g., a single covalent bond), a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C3 to C20 heteroarylene group, or a combination thereof,
X⁹ to X¹⁶ are each independently a single bond (e.g., a single covalent bond), —O—, —S—, —S(═O)—, —S(═O)₂—, —C(═O)—, —(CO)O—, —O(CO)O—, —C(═O)NH—, —NR^{b}— (wherein, R^{b} is hydrogen, deuterium, or a C1 to C10 alkyl group), or a combination thereof,
Y⁵ to Y⁸ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a combination thereof, and
* is a linking point.

A of Chemical Formula 6 and Chemical Formula 7 may each be represented by one or more selected from Chemical Formula A-1 to Chemical Formula A-4:

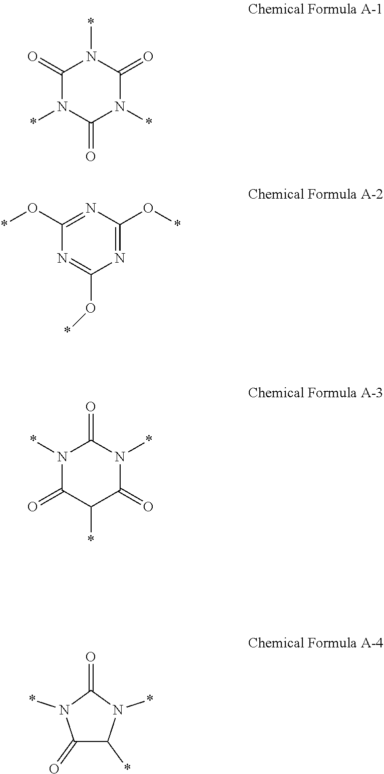

wherein, in Chemical Formula A-1 to Chemical Formula A-4, * is a linking point.
R⁷ and R⁸ may each independently be hydrogen, deuterium, a substituted or unsubstituted C1 to C10 alkyl group, or a combination thereof, L⁸ to L¹⁴ may each independently be a single bond (e.g., a single covalent bond), a substituted or unsubstituted C1 to C10 alkylene group, a substituted or unsubstituted C1 to C10 heteroalkylene group, or a combination thereof, X⁹ to X¹⁶ may each independently be a single bond (e.g., a single covalent bond), —O—, —S—, —C(═O)—, —(CO)O—, or a combination thereof, and Y⁵ to Y⁸ may each independently be a hydroxy group, a substituted or unsubstituted C1 to C10 alkyl group, a substituted or unsubstituted C2 to C10 alkenyl group, a substituted or unsubstituted C2 to C20 heterocycloalkyl group, or a combination thereof.

The structural unit represented by Chemical Formula 1 may be represented by one or more selected from Chemical Formulas 1-1 to 1-5:

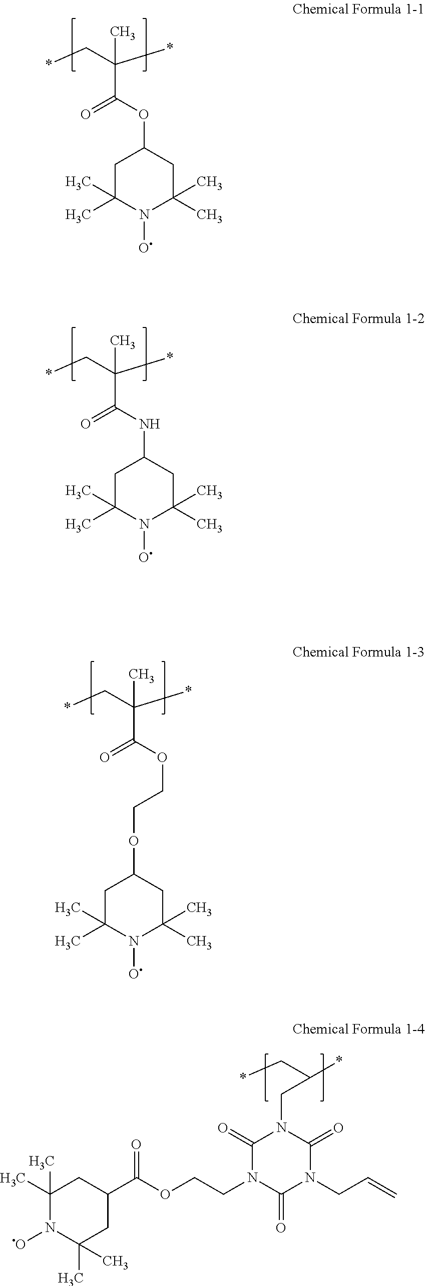

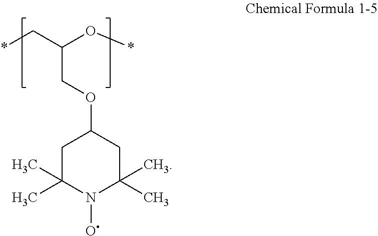

The polymer may include about 5 mol % to about 50 mol % of one or more structural units represented by Chemical Formula 1 to Chemical Formula 3, based on the number of moles of total structural units.

A weight average molecular weight of the polymer may be about 1,000 g/mol to about 300,000 g/mol.

The compound may be included in an amount of about 0.1 wt % to about 50 wt % based on a total weight of the resist underlayer composition.

The resist underlayer composition may further include additives such as a surfactant, a thermal acid generator, a photo acid generator, a plasticizer, or a combination thereof.

According to some embodiments, a method of forming a pattern includes forming a film to be etched on a substrate, coating the resist underlayer composition according to some embodiments on the film to be etched to form a resist underlayer, forming a photoresist pattern on the resist underlayer, and etching the resist underlayer and the film to be etched sequentially using the photoresist pattern as an etch mask.

The resist underlayer composition according to some embodiments may provide a resist underlayer that does not cause resist pattern collapse even in a fine patterning process.

Additionally, the resist underlayer composition according to some embodiments has improved sensitivity to an exposure light source, thereby providing a resist underlayer having excellent pattern formability and sensitivity.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-6 are cross-sectional views illustrating a method of forming a pattern using a resist underlayer composition according to some embodiments.

### DETAILED DESCRIPTION OF THE EMBODIMENTS

Example embodiments of the present disclosure will hereinafter be described in more detail, and may be easily performed by a person skilled in the art upon reviewing the present disclosure. However, the subject matter of this disclosure may be embodied in many different forms and is not construed as limited to the example embodiments set forth herein.

In the accompanying drawings, the thickness of layers, films, panels, regions, etc., may be exaggerated for clarity and like reference numerals designate like elements throughout the specification. It will be understood that if an element such as a layer, film, region, or substrate is referred to as being “on” another element, it may be directly on the other element or intervening elements may also be present. In contrast, if an element is referred to as being “directly on” another element, there are no intervening elements present.

As used herein, if a definition is not otherwise provided, ‘substituted’ refers to replacement of a hydrogen atom of a compound by a substituent selected from a deuterium, a halogen atom (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and a combination thereof.

In some embodiments, two adjacent substituents of the substituted halogen atom (F, Br, Cl, or I), hydroxy group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused together with each other to form a ring.

As used herein, if a definition is not otherwise provided, “hetero” refers to one including 1 to 3 heteroatoms selected from N, O, S, Se, and P.

As used herein, “aryl group” refers to a group having at least one hydrocarbon aromatic moiety, and broadly hydrocarbon aromatic moieties linked by a single bond (e.g., a single covalent bond) and a non-aromatic fused ring including hydrocarbon aromatic moieties fused directly or indirectly. An aryl group may be monocyclic, polycyclic, or fused polycyclic (e.g., rings sharing adjacent pairs of carbon atoms) functional group.

As used herein, “heterocyclic group” includes a heteroaryl group, and a cyclic group including at least one heteroatom selected from N, O, S, P, and Si instead of carbon © of a cyclic compound such as an aryl group, a cycloalkyl group, a fused ring thereof, or a combination thereof. If the heterocyclic group is a fused ring, each or entire ring of the heterocyclic group may include at least one heteroatom.

In some embodiments, a substituted or unsubstituted aryl group and/or a substituted or unsubstituted heterocyclic group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiophenyl group, a substituted or unsubstituted carbazolyl group, a pyridoindolyl group, a benzopyridooxazinyl group, a benzopyridothiazinyl group, a 9,9-dimethyl-9,10-dihydroacridinyl group, a combination thereof, or a combined fused ring of the foregoing groups, but is not limited thereto.

As used herein, if a specific definition is not otherwise provided, the term “combination” refers to mixing and/or copolymerization.

Additionally, as used herein, “polymer” may include both oligomers and polymers.

As used herein, if a definition is not otherwise provided, “weight average molecular weight” may be measured by dissolving a powder sample (the column may be Shodex LF-804 and the standard sample may be Shodex polystyrene) in tetrahydrofuran (THF) and using Agilent Technologies' 1200 series Gel Permeation Chromatography (GPC).

As used herein, if a definition is not otherwise provided, ‘*’ refers to a linking point of the structural unit of the compound or the moiety of the compound.

In the semiconductor industry, there is an effort to reduce the size of chips. Consequently, a line width of the resist patterned utilizing lithography technology should be reduced to a level of several tens of nanometers, and the pattern formed in this way is used to transfer the pattern to a lower material by using an etching process on a lower substrate. However, as the pattern size of the resist becomes smaller, a height (e.g., aspect ratio) of the resist that can withstand the line width is limited, and accordingly, the resists may not have suitable or sufficient resistance in the etching step. Therefore, a resist underlayer has been used to compensate for this if a thin resist material is used, if the substrate to be etched is thick, and/or if a deep pattern is required.

The resist underlayer should become thinner as the thickness of the resist becomes thinner, and the photoresist pattern should not collapse even if the resist underlayer is thin. For this purpose, the resist underlayer must have excellent adhesion to the photoresist. In some embodiments, in forming a thin resist underlayer, the coating uniformity of the resist underlayer composition and the flatness of the resist underlayer produced therefrom should be improved, and the sensitivity to the exposure light source should be improved to improve pattern formability and energy efficiency.

A resist underlayer composition according to some embodiments includes a polymer including a structural unit represented by Chemical Formula 1, a structural unit represented by Chemical Formula 2, a structural unit represented by Chemical Formula 3, or a combination thereof, and a solvent:

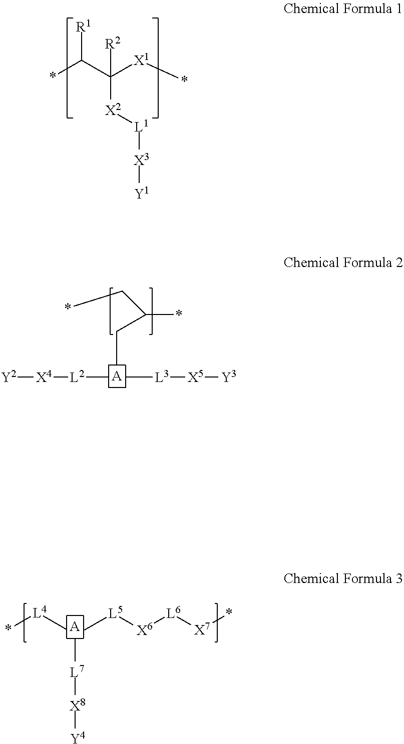

wherein, in Chemical Formula 1 to Chemical Formula 3,
R¹ and R² are each independently hydrogen, deuterium, a hydroxy group, a halogen atom, a substituted or unsubstituted C1 to C20 alkyl group, substituted or unsubstituted C2 to C20 alkenyl group, a substituted or unsubstituted C2 to C20 alkynyl group, or a combination thereof,
A is a heterocyclic group including a nitrogen atom in a ring,
L¹ to L⁷ are each independently a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C3 to C20 heterocycloalkylene group, a substituted or unsubstituted C6 to C20 arylene group, or a combination thereof,
X¹ to X⁸ are each independently a single bond (e.g., a single covalent bond), —O—, —S—, —S(═O)—, —S(═O)₂—, —C(═O)—, —(CO)O—, —O(CO)O—, —C(═O)NH—, —NR^{a}— (wherein, R^{a} is hydrogen, deuterium, or a C1 to C10 alkyl group), or a combination thereof,
Y¹ and Y⁴ are a group represented by Chemical Formula 4,
Y² and Y³ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C3 to C20 heterocycloalkyl group, a substituted or unsubstituted C6 to C20 aryl group, a group represented by Chemical Formula 4, or a combination thereof, and one or more selected from Y² and Y³ is a group represented by Chemical Formula 4, and
* is a linking point:

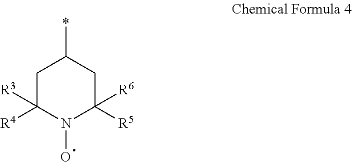

wherein, in Chemical Formula 4,
R³ to R⁶ are each independently hydrogen, deuterium, a substituted or unsubstituted C1 to C10 alkyl group, substituted or unsubstituted C2 to C10 alkenyl group, a substituted or unsubstituted C2 to C10 alkynyl group, or a combination thereof,
* is a linking point.

The polymer included in the composition according to some embodiments includes a group represented by Chemical Formula 4 in its structural unit, thereby being able to provide electrons to a highly reactive radical. While the present disclosure is not limited by any particular mechanism or theory, it is believed that the polymer can act as a radical scavenger that puts radicals in a stable state, and the resist underlayer composition including the polymer removes unnecessary radicals from the resist to improve the sensitivity of the resist and improve the pattern formability of fine patterns.

R¹ and R² of a structural unit represented by Chemical Formula 1 are each independently hydrogen, deuterium, a hydroxy group, a substituted or unsubstituted C1 to C20 alkyl group, substituted or unsubstituted C2 to C10 alkenyl group, or a combination thereof, for example hydrogen, a substituted or unsubstituted C1 to C20 alkyl group, or a combination thereof, for example hydrogen, or a substituted or unsubstituted C1 to C10 alkyl group, for example hydrogen, or a substituted or unsubstituted C1 to C5 alkyl group, for example hydrogen, a substituted or unsubstituted methyl group, a substituted or unsubstituted ethyl group, or a combination thereof, but are not limited thereto.

Because the structural unit represented by Chemical Formula 2 and the structural unit represented by Chemical Formula 3 include a hetero ring containing a nitrogen atom in the ring, polymers including these structural units are capable of sp2-sp2 bonds between polymers. While the present application is not limited by any particular mechanism or theory, it is believed that because of the foregoing the polymer may have a high electron density, and by including a polymer having a high electron density, the resist underlayer composition according to some embodiments can implement a film having a dense structure in the form of an ultra-thin film, and the high electron density of the polymer can have the effect of improving light absorption efficiency if exposing the resist underlayer composition to light. In some embodiments, the polymer containing the heterocyclic skeleton has excellent etch selectivity and can improve energy efficiency if forming patterns after exposure using high-energy rays such as EUV (Extreme ultraviolet; wavelength of about 13.5 nm) and E-Beam.

A in Chemical Formula 2 and Chemical Formula 3 is a heterocyclic group containing 2 or 3 nitrogen atoms in the ring, and may be for example, represented by any one selected from Chemical Formula A-1 to Chemical Formula A-4, for example Chemical Formula A-1, but is not limited thereto:

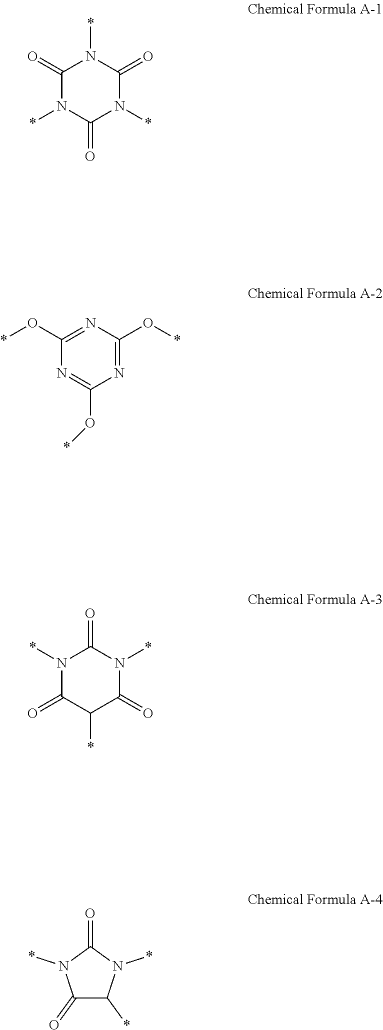

wherein, in Chemical Formula A-1 to Chemical Formula A-4, * is a linking point.
L¹ to L⁷ of Chemical Formula 1 to Chemical Formula 3 are each independently a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, or a combination thereof, for example, a single bond (e.g., a single covalent bond), a substituted or unsubstituted C1 to C10 alkylene group, a substituted or unsubstituted C2 to C10 alkenylene group, or a combination thereof, for example, a single bond (e.g., a single covalent bond), or a substituted or unsubstituted C1 to C10 alkylene group, or a combination thereof, but is not limited thereto.
X¹ to X⁸ are each independently a single bond (e.g., a single covalent bond), —O—, —S—, —S(═O)—, —C(═O)—, —(CO)O—, —O(CO)O—, —C(═O)NH—, or a combination thereof, for example, a single bond (e.g., a single covalent bond), —O—, —C(═O)—, —(CO)O—, —C(═O)NH—, or a combination thereof, but is not limited thereto.
Y² and Y³ of Chemical Formula 2 are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C3 to C20 heterocycloalkyl group, a group represented by Chemical Formula 4, or a combination thereof, for example hydroxy group, a substituted or unsubstituted C1 to C10 alkyl group, a substituted or unsubstituted C2 to C10 alkenyl group, a group represented by Chemical Formula 4, or a combination thereof, provided that one or more selected from Y² and Y³ is a group represented by Chemical Formula 4, but is not limited thereto.
Y¹ in Chemical Formula 1 and Y⁴ in Chemical Formula 3 are a group represented by Formula 4:

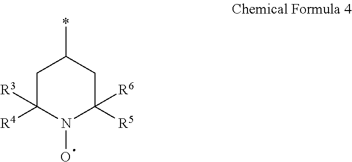

R³ to R⁶ are each independently hydrogen, deuterium, a substituted or unsubstituted C1 to C10 alkyl group, substituted or unsubstituted C2 to C10 alkenyl group, or a combination thereof, for example hydrogen, deuterium, a substituted or unsubstituted C1 to C10 alkyl group, or a combination thereof, for example hydrogen, a substituted or unsubstituted C1 to C5 alkyl group, or a combination thereof, for example hydrogen, a substituted or unsubstituted methyl group, a substituted or unsubstituted ethyl group, or a combination thereof, for example R³ to R⁶ may all be a substituted or unsubstituted methyl group, but is not limited thereto.

For example, the structural unit represented by Chemical Formula 1 may be represented by one or more selected from Chemical Formula 1-1 to Chemical Formula 1-5:

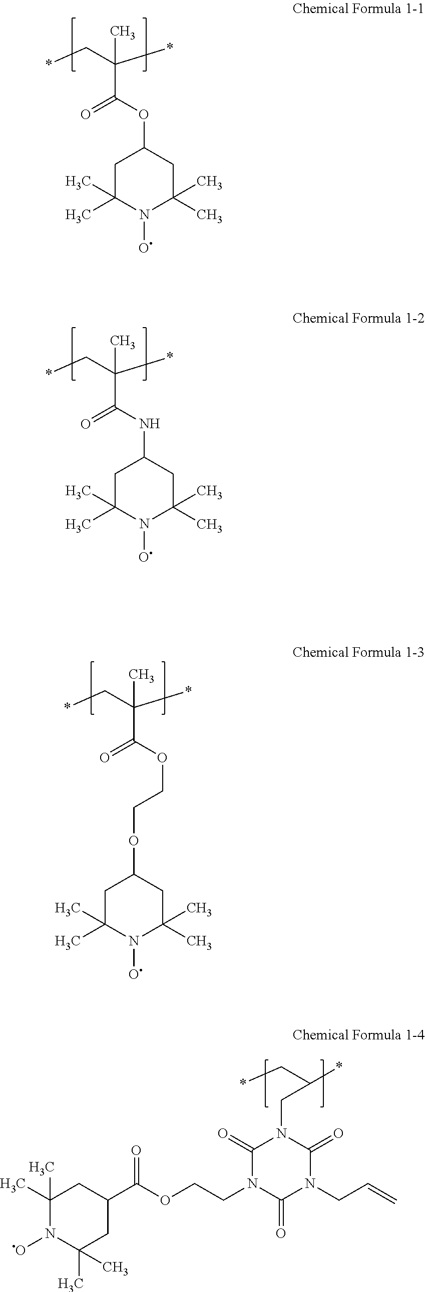

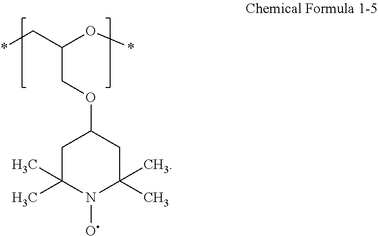

The polymer included in the resist underlayer composition according to some embodiments includes at least one selected from the structural units represented by Chemical Formula 1 to above Chemical Formula 3 in an amount of about 5 mol % to about 50 mol %, for example, about 10 mol % to about 50 mol %, or about 20 mol % to about 40 mol %, based on the number of moles of all structural units forming the polymer. In the composition according to some embodiments, the polymer includes one or more selected from the structural units represented by Chemical Formula 1 to Chemical Formula 3 within the above ranges, so that if applied as a resist underlayer, the composition according to some embodiments can remove unnecessary radicals from the resist, improve the sensitivity of the resist, and improve pattern formability of fine patterns.

In some embodiments, the polymer may further include a structural unit represented by Chemical Formula 5, a structural unit represented by Chemical Formula 6, a structural unit represented by Chemical Formula 7, or a combination thereof:

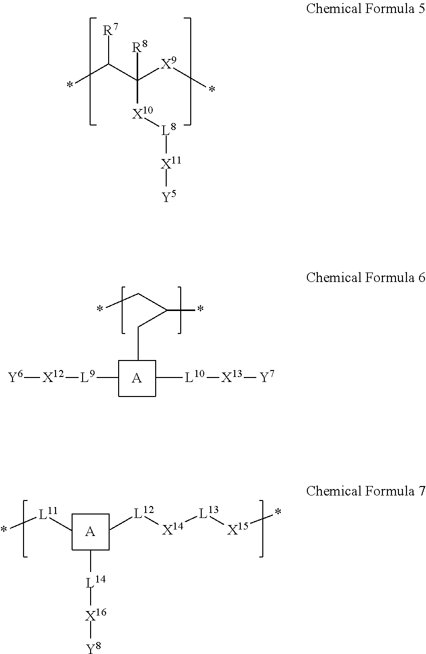

wherein, in Chemical Formula 5 to Chemical Formula 7,
R⁷ and R⁸ are each independently hydrogen, deuterium, a hydroxy group, a halogen atom, a substituted or unsubstituted C1 to C20 alkyl group, substituted or unsubstituted C2 to C20 alkenyl group, a substituted or unsubstituted C2 to C20 alkynyl group, or a combination thereof,
A is a heterocyclic group including a nitrogen atom in a ring,
L⁸ to L¹⁴ are each independently a single bond (e.g., a single covalent bond), a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C3 to C20 heteroarylene group, or a combination thereof,
X⁹ to X¹⁶ are each independently a single bond (e.g., a single covalent bond), —O—, —S—, —S(═O)—, —S(═O)₂—, —C(═O)—, —(CO)O—, —O(CO)O—, —C(═O)NH—, —NR^{b}— (wherein, R^{b} is hydrogen, deuterium, or a C1 to C10 alkyl group), or a combination thereof,
Y⁵ to Y⁸ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a combination thereof, and
* is a linking point.

The structural units represented by Chemical Formula 5 to Chemical Formula 7 differ from the structural units represented by Chemical Formula 1 to Chemical Formula 3 only in that they do not contain substituents each represented by Chemical Formula 4. The rest have the same definitions as defined with respect to Chemical Formula 1 to Chemical Formula 3, and a polymer including these structural units can satisfy various suitable requirements or features for forming a resist underlayer.

R⁷ and R⁸ of Chemical Formula 5 are each independently hydrogen, deuterium, a hydroxy group, a substituted or unsubstituted C1 to C20 alkyl group, substituted or unsubstituted C2 to C10 alkenyl group, or a combination thereof, for example hydrogen, a substituted or unsubstituted C1 to C20 alkyl group, or a combination thereof, for example hydrogen, or a substituted or unsubstituted C1 to C10 alkyl group, for example hydrogen, or a substituted or unsubstituted C1 to C5 alkyl group, for example hydrogen, a substituted or unsubstituted methyl group, a substituted or unsubstituted ethyl group, or a combination thereof, but is not limited thereto.

A of Chemical Formula 6 and Chemical Formula 7 may be represented by one or one or more selected from Chemical Formula A-1 to Chemical Formula A-4.

L⁸ to L¹⁴ are each independently a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C1 to C10 heteroalkylene group, or a combination thereof, for example a single bond (e.g., a single covalent bond), a substituted or unsubstituted C1 to C10 alkylene group, a substituted or unsubstituted C1 to C10 heteroalkylene group, or a combination thereof, for example a single bond (e.g., a single covalent bond), a substituted or unsubstituted C1 to C5 alkylene group, a C1 to C5 heteroalkylene group containing a substituted or unsubstituted sulfur atom, or a combination thereof, but is not limited thereto.

X⁹ to X¹⁶ are each independently a single bond (e.g., a single covalent bond), —O—, —S—, —S(═O)—, —C(═O)—, —(CO)O—, —O(CO)O—, —C(═O)NH—, or a combination thereof, for example —O—, —S—, —C(═O)—, —(CO)O—, —O(CO)O—, or a combination thereof, but are not limited thereto.

Y⁵ to Y⁸ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a combination thereof, for example hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C20 heterocycloalkyl group, or a combination thereof, for example hydroxy group, a substituted or unsubstituted C1 to C10 alkyl group, a substituted or unsubstituted C2 to C10 alkenyl group, a substituted or unsubstituted C2 to C20 heterocycloalkyl group, or a combination thereof, for example hydroxy group, a substituted or unsubstituted C1 to C5 alkyl group, a substituted or unsubstituted C2 to C5 alkenyl group, or a combination thereof, but are not limited thereto.

As an example, the structural unit represented by Chemical Formula 5 may be represented by any one selected from Chemical Formula 5-1 to Chemical Formula 5-3, the structural unit represented by Chemical Formula 6 may be represented by any one selected from Chemical Formula 6-1 to Chemical Formula 6-3, and the structural unit represented by Chemical Formula 7 may be represented by any one selected from Chemical Formula 7-1 to Chemical Formula 7-3:

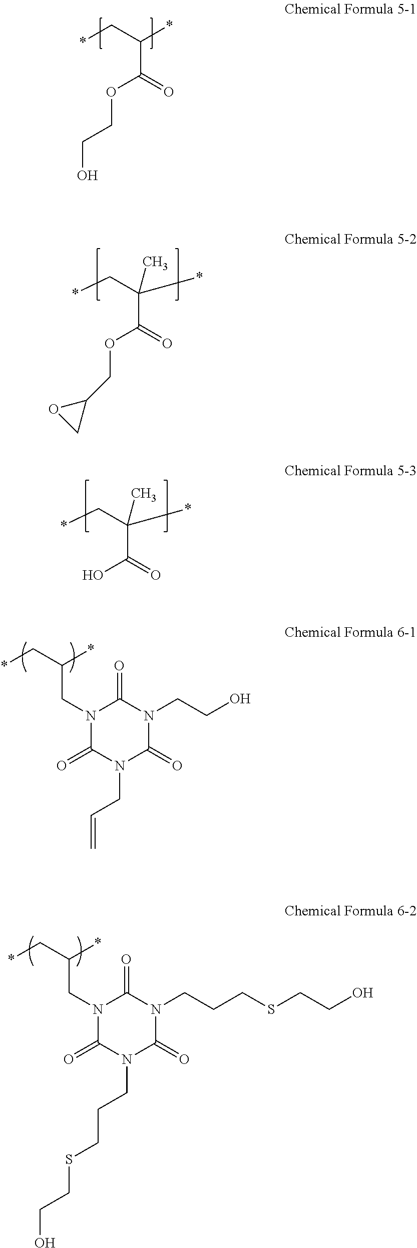

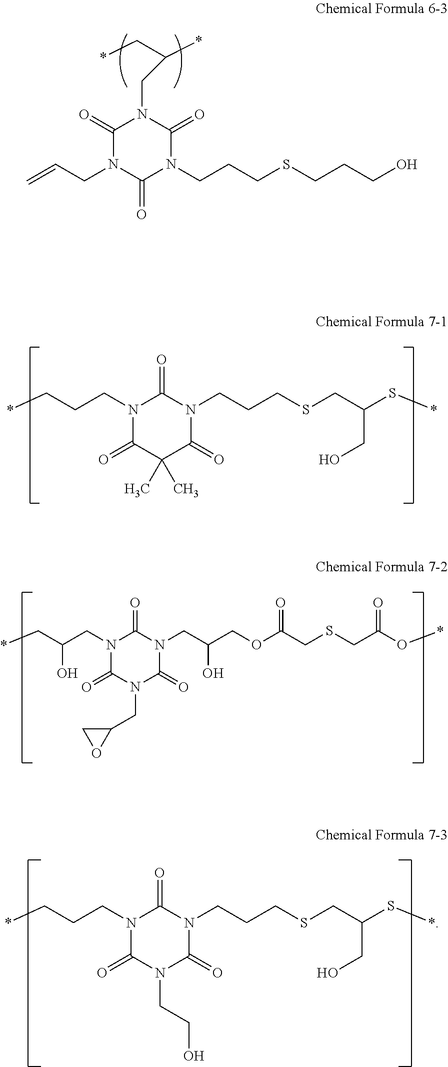

The polymer may have a weight average molecular weight of about 1,000 g/mol to about 300,000 g/mol, for example about 3,000 g/mol to about 200,000 g/mol, for example about 3,000 g/mol to about 100,000 g/mol, for example about 3,000 g/mol to about 90,000 g/mol, for example about 3,000 g/mol to about 70,000 g/mol, for example about 3,000 g/mol to about 70,000 g/mol, for example about 3,000 g/mol to about 50,000 g/mol, for example about 5,000 g/mol to about 50,000 g/mol, or, for example, about 5,000 g/mol to about 30,000 g/mol, but is not limited thereto. By having a weight average molecular weight within the above ranges, a carbon content and solubility in the solvent of the resist underlayer composition including the polymer may be adjusted and/or optimized or improved.

The polymer may be included in an amount of about 0.1 wt % to about 50 wt % based on a total weight of the resist underlayer composition. In some embodiments, the polymer may be included in an amount of about 10 wt % to about 50 wt %, for example about 20 wt % to about 50 wt %, or, for example about 20 wt % to about 30 wt %, based on a total weight of the resist underlayer composition, but is not limited thereto. By including the polymer within the above ranges in the composition, the thickness, surface roughness, and a degree of planarization of the resist underlayer may be adjusted.

The resist underlayer composition according to some embodiments may include a solvent. The solvent is not particularly limited as long as it has suitable or sufficient solubility and/or dispersibility for the polymer and compound according to some embodiments, but may be, for example, propylene glycol, propylene glycol diacetate, methoxypropanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, methyl 2-hydroxyisobutyrate, acetylacetone, ethyl 3-ethoxypropionate, or a combination thereof.

The resist underlayer composition according to some embodiments may further include one or more additional polymers selected from an acrylic resin, an epoxy resin, a novolac-based resin, a glycoluril-based resin, and a melamine-based resin, in addition to the polymer, compound, and solvent, but is not limited thereto.

The resist underlayer composition according to some embodiments may further include an additive including a surfactant, a thermal acid generator, a plasticizer, or a combination thereof.

The surfactant may be used to improve coating defects that occur as the solid content increases if forming a resist underlayer. For example, the surfactant may be an alkylbenzenesulfonic acid salt, an alkylpyridinium salt, polyethylene glycol, a quaternary ammonium salt, etc., but is not limited thereto.

The thermal acid generator may be, for example, an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalenecarboxylic acid, and/or benzoin tosylate, 2-nitrobenzyltosylate, and/or other organic sulfonic acid alkyl esters, but is not limited thereto.

The plasticizer is not particularly limited, and various suitable types (or kinds) of plasticizers generally used in the art may be used. Examples of the plasticizer may include low molecular weight compounds such as phthalic acid esters, adipic acid esters, phosphoric acid esters, trimellitic acid esters, and citric acid esters, and polyether-based, polyester-based, and polyacetal-based compounds.

According to some embodiments, a resist underlayer manufactured using the aforementioned resist underlayer composition is provided. The resist underlayer may be, for example, obtained by coating the aforementioned resist underlayer composition on a substrate and then curing through a heat treatment process.

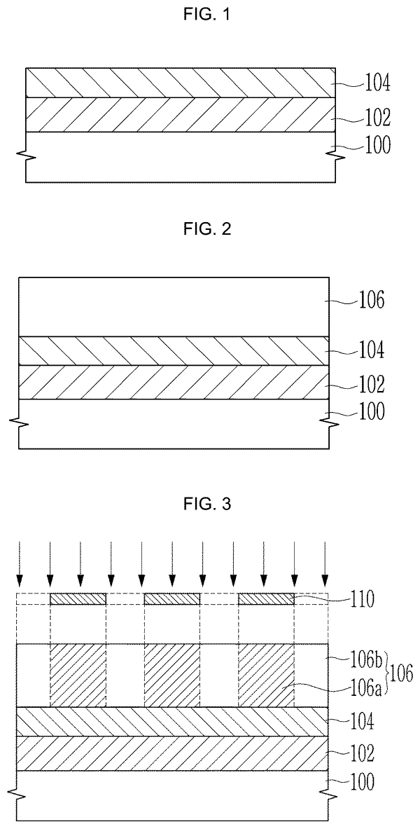

Hereinafter, a method of forming a pattern using the aforementioned resist underlayer composition will be described with reference to FIGS. 1-6. FIGS. 1-6 are cross-sectional views illustrating a method of forming a pattern using the resist underlayer composition according to embodiments of the present disclosure.

Referring to FIG. 1, first, an object to be etched is prepared. An example of the object to be etched may be a thin film 102 on a semiconductor substrate 100. Hereinafter, only embodiments where the object to be etched is the thin film 102 will be described, but the present disclosure is not limited thereto. The surface of the thin film 102 is cleaned to remove contaminants remaining on the thin film 102. The thin film 102 may be, for example, a silicon nitride film, a polysilicon film, and/or a silicon oxide film.

Subsequently, the aforementioned resist underlayer composition is coated on the surface of the cleaned thin film 102 using, for example, a spin coating method.

Then, drying and baking processes are performed to form a resist underlayer 104 on the thin film. The baking treatment may be performed at about 100° C. to about 500° C., for example, at about 100° C. to about 300° C. A more detailed description of the resist underlayer composition is not repeated here to avoid duplication because it has been described in more detail above.

Referring to FIG. 2, a photoresist is coated on the resist underlayer 104 to form a photoresist layer 106. In some embodiments, the photoresist composition forming the photoresist layer 106 may include an organometallic compound including Sn, a solvent, etc., but is not limited thereto.

Subsequently, a first baking process is performed to heat the substrate 100 on which the photoresist layer 106 is formed. The first baking process may be performed at a temperature of about 90° C. to about 120° C.

Referring to FIG. 3, the photoresist layer 106 is selectively exposed. To explain the exposure process for exposing the photoresist layer 106 as an example, an exposure mask having a set or predetermined pattern is placed on the mask stage of an exposure apparatus, and an exposure mask 110 is placed on the photoresist layer 106. Subsequently, by irradiating light to the mask 110, a set or predetermined portion of the photoresist layer 106 formed on the substrate 100 selectively reacts with the light passing through the exposure mask.

For example, examples of light that can be used in the exposure process may include short-wavelength light such as i-line activating radiation having a wavelength of 365 nm, a KrF excimer laser having a wavelength of 248 nm, and an ArF excimer laser having a wavelength of 193 nm. In some embodiments, EUV (Extreme ultraviolet), which has a wavelength of 13.5 nm, which corresponds to extreme ultraviolet light, may be used.

The exposed region 106b of the photoresist layer 106 has a different solubility from the unexposed region 106a of the photoresist layer 106 as a polymer is formed through a crosslinking reaction such as condensation reaction between organometallic compounds.

Subsequently, a second baking process is performed on the substrate 100. The second baking process may be performed at a temperature of about 90° C. to about 200° C. By performing the second baking process, the exposed region 106b of the photoresist layer 106 becomes difficult to dissolve in the developer.

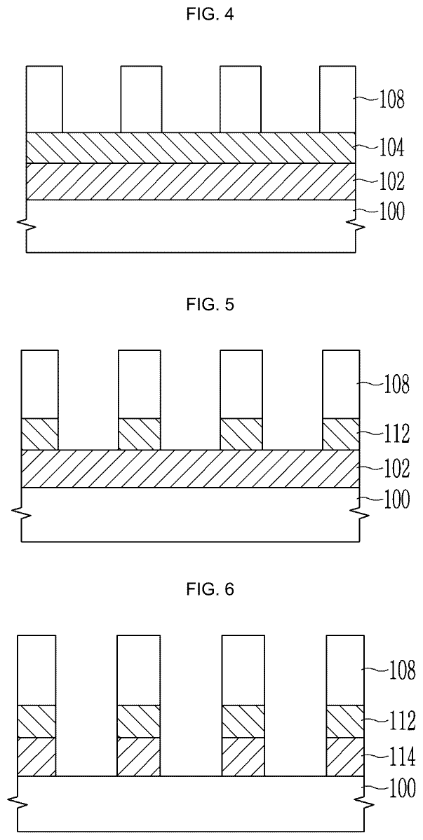

Referring to FIG. 4, the photoresist layer 106a corresponding to the unexposed region is dissolved and removed using an organic solvent developer such as 2-heptanone, and thereby the photoresist layer 106b remaining after development forms a photoresist pattern 108.

As described above, the developer used in the method of forming a pattern according to some embodiments may be an organic solvent. Examples of organic solvents used in the method of forming a pattern according to some embodiments may include ketones such as methyl ethyl ketone, acetone, cyclohexanone, and 2-heptanone, alcohols such as 4-methyl-2-propanol, 1-butanol, isopropanol, and 1-propanol, methanol, esters such as propylene glycol monomethyl ether acetate, ethyl acetate, ethyl lactate, n-butyl acetate, and butyrolactone, aromatic compounds such as benzene, xylene, and toluene, or a combination thereof.

However, the photoresist pattern according to some embodiments is not necessarily limited to being formed as a negative tone image, and may be formed to have a positive tone image. In some embodiments, the developer that can be used to form a positive tone image may be a quaternary ammonium hydroxide composition such as tetraethylammonium hydroxide, tetrapropylammonium hydroxide, tetrabutylammonium hydroxide, or a combination thereof.

As explained above, the photoresist pattern 108 formed by exposure to high-energy light such as not only light having wavelengths such as i-line (wavelength: 365 nm), KrF excimer laser (wavelength: 248 nm), and/or ArF excimer laser (wavelength: 193 nm), but also EUV (Extreme UltraViolet; wavelength: 13.5 nm) and/or an E-Beam may have a width of about 5 nm to about 100 nm thick. For example, the photoresist pattern 108 may be formed to have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In some embodiments, the photoresist pattern 108 may have a pitch having a half-pitch of less than or equal to about 50 nm, for example less than or equal to about 40 nm, for example less than or equal to about 30 nm, for example less than or equal to about 20 nm, or for example less than or equal to about 10 nm and a line width roughness of less than or equal to about 5 nm, less than or equal to about 3 nm, less than or equal to about 2 nm, or less than or equal to about 1 nm.

Subsequently, the resist underlayer 104 is etched using the photoresist pattern 108 as an etch mask. An organic layer pattern 112 as shown in FIG. 5 is formed through the above etching process.

The formed organic layer pattern 112 may also have a width corresponding to the photoresist pattern 108. The etching may be performed, for example, by dry etching using an etching gas, and the etching gas may be, for example, CHF₃, CF₄, Cl₂, O₂, or a mixture thereof. As described above, because the resist underlayer formed by the resist underlayer composition according to some embodiments has a fast etch rate, a smooth etching process can be performed within a short time.

Referring to FIG. 6, the exposed thin film 102 is etched by applying the photoresist pattern 108 as an etch mask. As a result, the thin film is formed into a thin film pattern 114.

In the exposure process performed as described above, the thin film pattern formed by the exposure process performed using short-wavelength light sources such as the activating radiation i-line (wavelength: 365 nm), KrF excimer laser (wavelength: 248 nm), and/or ArF excimer laser (wavelength: 193 nm) 114) may have a width of tens to hundreds of nanometers and the thin film pattern 114 formed by an exposure process performed using an EUV light source may have a width of less than or equal to about 20 nm.

Hereinafter, embodiments of the present disclosure will be described in more detail through examples related to the synthesis of the aforementioned polymer and the preparation of a resist underlayer composition including the same. However, the present disclosure is not technically limited by the following examples.

### Synthesis of Polymers

### Synthesis Example 1

9 g of 2,2,6,6-tetramethylpiperidine methacrylate, 24.9 g of 1,3,5-triallyl-1,3,5-triazinane-2,4,6-trione, 3.7 g of mercapto ethanol, 0.7 g of AIBN (azobisisobutyronitrile), and 48 g of N,N-dimethylformamide (DMF) are added to a 500 mL three-necked round flask and a condenser is connected thereto. The temperature is raised to 80° C. in a nitrogen atmosphere, and after a reaction proceeds for 12 hours, the resultant reaction solution is cooled to room temperature. Subsequently, the reaction solution is washed three times with 200 mL of ethyl ether, then filtered and the solvent is removed to obtain Compound (A).

23.7 g of Compound (A) is added to 170 mL of dichloromethane in a 500 mL two-necked round flask and an argon atmosphere is created. After dissolving 15.75 g of m-chloroperbenzoic acid in 105 mL of dichloromethane, it is slowly added dropwise to the flask including Intermediate (A) and a reaction proceeds for 3 hours. After completion of the reaction, the resultant organic layer is separated and dried with 250 mL of water using a separatory funnel to finally obtain a polymer (weight average molecular weight (Mw)=18,000 g/mol) represented by Chemical Formula 1A. (x: 28.5 mol %, y: 71.5 mol %)

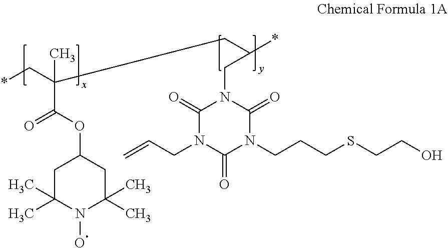

### Synthesis Example 2

9 g of N-(2,2,6,6-tetramethyl-4-piperidyl)methacrylamide, 24.9 g of 1,3,5-triallyl-1,3,5-triazinane-2,4,6-trione, 3.7 g of mercapto ethanol, 0.7 g of AIBN (azobisisobutyronitrile), and 48 g of N,N-dimethylformamide (DMF) are added to a 500 mL three-necked round flask and a condenser is connected thereto. The temperature is raised to 80° C. in a nitrogen atmosphere, and after a reaction proceeds for 12 hours, the resultant reaction solution is cooled to room temperature.

Subsequently, the reaction solution is washed three times with 200 mL of ethyl ether, then filtered and the solvent is removed to obtain Compound (B).

27 g of Compound (B) is added to 170 mL of dichloromethane in a 500 mL two-necked round flask and an argon atmosphere is created. After dissolving 15.75 g of m-chloroperbenzoic acid in 105 mL of dichloromethane, it is slowly added dropwise to the flask including Intermediate (B) and a reaction proceeds for 3 hours. After completion of the reaction, the resultant organic layer is separated and dried with 250 mL of water using a separatory funnel to finally obtain a polymer (weight average molecular weight (Mw)=15,000 g/mol) including a structural unit represented by Chemical Formula 1B. (x: 28.5 mol %, y: 71.5 mol %)

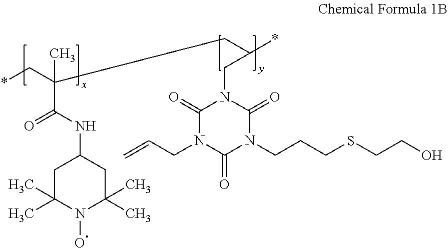

### Synthesis Example 3

11.4 g of 2-[(2,2,6,6-tetramethyl-4-piperidinyl)oxy]ethyl 2-methyl-2-propenoate 11.4 g, 24.9 g of 1,3,5-triallyl-1,3,5-triazinane-2,4,6-trione, 3.7 g of mercapto ethanol, 0.7 g of AIBN (azobisisobutyronitrile), and 48 g of N,N-dimethyl formamide (DMF) are added to a 500 mL three-necked round flask and a condenser is connected thereto. The temperature is raised to 80° C. in a nitrogen atmosphere, and after a reaction proceeds for 12 hours, the resultant reaction solution is cooled to room temperature. Subsequently, the reaction solution is washed three times with 200 mL of ethyl ether, then filtered and the solvent is removed to obtain compound (C).

20 g of Compound (C) is added to 170 mL of dichloromethane in a 500 mL two-necked round flask and an argon atmosphere is created. After dissolving 15.75 g of m-chloroperbenzoic acid in 105 mL of dichloromethane, it is slowly added dropwise to the flask including Intermediate (C) and a reaction proceeds for 3 hours. After completion of the reaction, the resultant organic layer is separated and dried with 250 mL of water using a separatory funnel to finally obtain 13 g of a polymer (weight average molecular weight (Mw)=17,000 g/mol) including a structural unit represented by Chemical Formula 1C. (x: 30 mol %, y: 70 mol %)

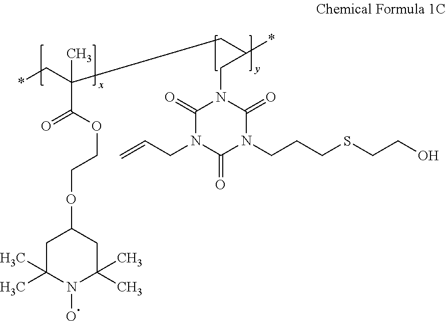

### Synthesis Example 4

2.4 g of 1,3-diallyl-5-(2-hydroxyethyl) isocyanurate, 0.7 g of AIBN (azobisisobutyronitrile) 0.7 g, and 48 g of N,N-dimethyl formamide (DMF) 48 g are added to a 500 mL three-necked round flask and a condenser is connected thereto. A reaction proceeds at 80° C. for 16 hours, and then the resultant reaction solution is cooled to room temperature. The reaction solution is added dropwise with stirring to a 1 L wide-mouth bottle including 800 g of water to generate gum, and then dissolved in 80 g of tetrahydrofuran (THF). The dissolved resin solution is formed into a precipitate using toluene, and single and low molecular weight molecules are removed to obtain Compound (D).

10 g of Compound (D), 2.2 g of 4-carboxy-2,2,6,6-tetramethyl-1-piperidinyloxy, 1.36 g of 1-ethyl-3-(3-dimethylaminopropyl)carbodiimide, and 134 mg of 4-dimethylaminopyridine are added to 140 mL of dichloromethane in a 500 mL three-necked round flask. The reactants are reacted at argon atmosphere and room temperature for 24 hours. After completion of the reaction, dilution with 300 mL of dichloromethane using a separatory funnel proceeds, and the resultant reaction mixture is treated with 300 mL of aqueous hydrochloric acid (2 M concentration), and washed with 300 mL of brine. Afterwards, the organic layer is separated with 300 mL of water and dried to finally obtain 8 g of a polymer (Mw=11,000 g/mol) including a structural unit represented by Chemical Formula 1 D. (x: 34 mol %, y: 66 mol %)

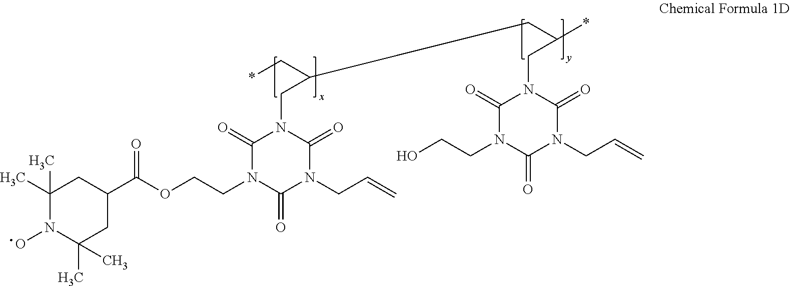

### Synthesis Example 5

24.9 g of 1,3-diallyl-5-(2-hydroxyethyl) isocyanurate, 0.7 g of AIBN (azobisisobutyronitrile), and 48 g of N,N-dimethyl formamide (DMF) are added to a 500 mL three-necked round flask and a condenser is connected thereto. A reaction proceeds at 80° C. for 16 hours, and then the resultant reaction solution is cooled to room temperature. The reaction solution is added dropwise with stirring to a 1 L wide-mouth bottle including 800 g of water to generate gum, and then dissolved in 80 g of tetrahydrofuran (THF). The dissolved resin solution is formed into a precipitate using toluene, and single and low molecular weight molecules are removed to finally obtain a polymer (Mw=10,500 g/mol) composed of structural units represented by Chemical Formula 6-1.

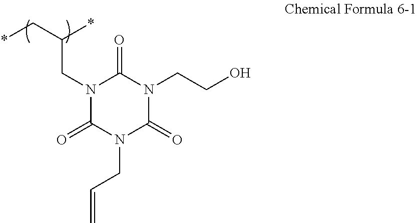

### Synthesis Example 6

24.9 g of 1,3,5-triallyl-1,3,5-triazinane-2,4,6-trione, 7.4 g of mercapto ethanol, 0.7 g of AIBN (azobisisobutyronitrile), and 48 g of N,N-dimethyl formamide (DMF) are added to a 500 mL three-necked round flask and a condenser is connected thereto. A reaction proceeds at 80° C. for 16 hours, and then the reaction solution is cooled to room temperature. The resultant reaction solution is added dropwise with stirring to a 1 L wide-mouth bottle including 800 g of water to generate gum, and then dissolved in 80 g of tetrahydrofuran (THF). The dissolved resin solution is formed into a precipitate using toluene, and single and low molecular weight molecules are removed to finally obtain a polymer (Mw=8,000 g/mol) composed of structural units represented by Chemical Formula 6-2.

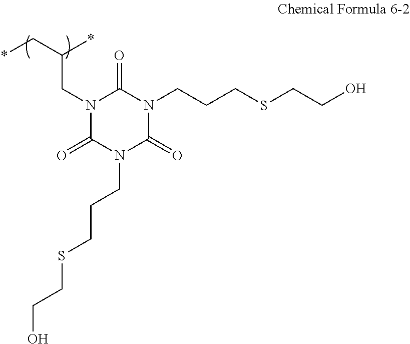

### Preparation of Resist Underlayer Compositions

### Example 1

1.2 g of the polymer obtained in Synthesis Example 1, 0.4 g of PD1174 (crosslinking agent), and 0.02 g of pyridinium para-toluenesulfonate (PPTS) are mixed together and completely dissolved in propylene glycol monomethyl ether to a 3% solid content, and then diluted with an additional solvent to prepare a resist underlayer composition.

### Example 2

A resist underlayer composition is prepared in the same manner as in Example 1, except that the polymer obtained in Synthesis Example 2 is used instead of the polymer obtained in Synthesis Example 1.

### Example 3

A resist underlayer composition is prepared in the same manner as in Example 1, except that the polymer obtained in Synthesis Example 3 is used instead of the polymer obtained in Synthesis Example 1.

### Example 4

A resist underlayer composition is prepared in the same manner as in Example 1, except that the polymer obtained in Synthesis Example 4 is used instead of the polymer obtained in Synthesis Example 1.

### Example 5

A resist underlayer composition is prepared in the same manner as in Example 1, except that 1 g of the polymer obtained in Synthesis Example 5 is further included.

### Example 6

A resist underlayer composition is prepared in the same manner as in Example 2, except that 1 g of the polymer obtained in Synthesis Example 5 is further included.

### Example 7

A resist underlayer composition is prepared in the same manner as in Example 3, except that 1 g of the polymer obtained in Synthesis Example 5 is further included.

### Example 8

A resist underlayer composition is prepared in the same manner as in Example 4, except that 1 g of the polymer obtained in Synthesis Example 5 is further included.

### Example 9

A resist underlayer composition is prepared in the same manner as in Example 1, except that 1 g of the polymer obtained in Synthesis Example 6 is further included.

### Comparative Example 1

1.2 g of the polymer obtained in Synthesis Example 5, 0.4 g of PD1174 (crosslinking agent), and 0.02 g of pyridinium para-toluenesulfonate (PPTS) are mixed together and completely dissolved in propylene glycol monomethyl ether to a 3% solid content, and then diluted with an additional solvent to prepare a resist underlayer composition.

### Comparative Example 2

1.2 g of the polymer obtained in Synthesis Example 6, 0.4 g of PD1174 (crosslinking agent), and 0.02 g of pyridinium para-toluenesulfonate (PPTS) are mixed together and completely dissolved in propylene glycol monomethyl ether to a 3% solid content, and then diluted with an additional solvent to prepare a resist underlayer composition.

### Evaluation 1: Coating Uniformity Evaluation

Each of the compositions according to the examples and the comparative examples is taken by 2 mL and cast on an 8-inch wafer and then, spin-coated at a main spin speed of 1,500 rpm for 20 seconds by using an auto track (ACT-8, TEL (Tokyo Electron Limited)) and cured at 205° C. for 60 seconds to form a 50 Å-thick thin film.

The film is measured with respect to thicknesses at 51 points along its horizontal axis, and as shown in Calculation Equation 1, a difference of maximum and minimum values of the thicknesses measured at the 51 points is calculated to evaluate coating uniformity. The smaller the following coating uniformity value, the better coating uniformity, and the results are shown in Table 1.

$$Coating uniformity ( \% ) = \qquad [ Calculation Equation 1 ]$$

$$( maximum value of thicknesses measured at 51 points in the wafer -$$

$$minimum value ) / average thickness \times 100$$

TABLE 1

| | Coating |
|---|---|
| | uniformity |
| | (%) |
| Example 1 | 2.5 |
| Example 2 | 2.0 |
| Example 3 | 2.2 |
| Example 4 | 2.4 |
| Example 5 | 2.2 |
| Example 6 | 2.7 |
| Example 7 | 2.6 |
| Example 8 | 2.5 |
| Example 9 | 2.0 |
| Comparative | 4.1 |
| Example 1 | |
| Comparative | 4.2 |
| Example 2 | |

Referring to Table 1, the coating uniformity of the resist underlayers formed from the compositions according to the examples is better than those of the layers formed from the compositions according to the comparative examples.

### Evaluation 2: Chemical Resistance Evaluation

Each of the resist underlayer compositions according to the examples and the comparative examples is taken by 2 mL and cast on a 4-inch wafer and then, spin-coated at 1,500 rpm for 20 seconds by using a spin coater (Mikasa Co., Ltd.). Subsequently, the coated composition is cured at 210° C. for 90 seconds to form a thin film, of which a thickness is measured by using a thin film thickness meter manufactured by K-MAC. Then, the thin film is soaked in a mixed solvent (70 wt % of propylene glycol monomethyl ether+30 wt % of propylene glycol monomethylether acetate) for 1 minute and taken out therefrom to measure a thickness. The obtained underlayer is evaluated with respect to chemical resistance by calculating a thickness reduction rate before and after the soaking as shown in Calculation Equation 2. The smaller the following thickness reduction rate, the better chemical resistance, and the results are shown in Table 2.

$$Underlayer thickness reduction rate ( \% ) = \qquad [ Calculation Equation 2 ]$$

$$\{ ( thin film thickness before soaking - thin film thickness after soaking ) /$$

$$thin film thickness before soaking \} \times 100$$

TABLE 2

| | Thickness |
|---|---|
| | reduction |
| | rate (%) |
| Example 1 | 0.5 |
| Example 2 | 0.3 |
| Example 3 | 0.2 |
| Example 4 | 0.6 |
| Example 5 | 0.1 |
| Example 6 | 0.5 |
| Example 7 | 0.4 |
| Example 8 | 0.5 |
| Example 9 | 0.7 |
| Comparative | 0.7 |
| Example 1 | |
| Comparative | 1.9 |
| Example 2 | |

Referring to Table 2, the chemical resistances of the resist underlayers formed from the composition according to the Examples are equal to or superior to those of the Comparative Examples.

Hereinbefore, example embodiments of the present disclosure have been described and illustrated, however, it should be apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Description of Symbols

| | |
|---|---|
| 100: substrate | 102: thin film |
| 104: resist underlayer | 106: photoresist layer |
| 106a: unexposed region | 106b: exposed region |
| 108: photoresist pattern | 110: mask |
| 112: organic layer pattern | 114: thin film pattern |

What is claimed is:

1. A resist underlayer composition, comprising:
a polymer comprising a structural unit represented by Chemical Formula 1, a structural unit represented by Chemical Formula 2, a structural unit represented by Chemical Formula 3, or a combination thereof, and a solvent: 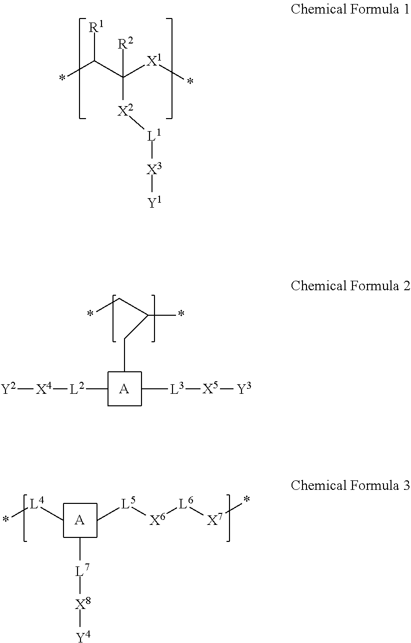
wherein, in Chemical Formula 1 to Chemical Formula 3,
R¹ and R² are each independently hydrogen, deuterium, a hydroxy group, a halogen atom, a substituted or unsubstituted C1 to C20 alkyl group, substituted or unsubstituted C2 to C20 alkenyl group, a substituted or unsubstituted C2 to C20 alkynyl group, or a combination thereof,
A is a heterocyclic group including a nitrogen atom in a ring,
L¹ to L⁷ are each independently a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C3 to C20 heterocycloalkylene group, a substituted or unsubstituted C6 to C20 arylene group, or a combination thereof,
X¹ to X⁸ are each independently a single bond, —O—, —S—, —S(═O)—, —S(═O)₂—, —C(═O)—, —(CO)O—, —O(CO)O—, —C(═O)NH—, —NR^{a}— (wherein, R^{a} is hydrogen, deuterium, or a C1 to C10 alkyl group), or a combination thereof,
Y¹ and Y⁴ are each a group represented by Chemical Formula 4,
Y² and Y³ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C3 to C20 heterocycloalkyl group, a substituted or unsubstituted C6 to C20 aryl group, a group represented by Chemical Formula 4, or a combination thereof, provided that one or more selected from Y² and Y³ is a group represented by Chemical Formula 4, and
* is a linking point: 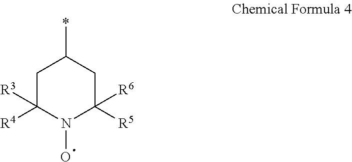
wherein, in Chemical Formula 4,
R³ to R⁶ are each independently hydrogen, deuterium, a substituted or unsubstituted C1 to C10 alkyl group, substituted or unsubstituted C2 to C10 alkenyl group, a substituted or unsubstituted C2 to C10 alkynyl group, or a combination thereof, and
* is a linking point.

2. The resist underlayer composition as claimed in claim 1, wherein R¹ and R² are each independently hydrogen, or a substituted or unsubstituted C1 to C20 alkyl group, A is a moiety represented by Chemical Formula A-1, L¹ to L⁷ are each independently a single bond, or a substituted or unsubstituted C1 to C10 alkylene group, R¹ and R² are each independently hydrogen, deuterium, a substituted or unsubstituted C1 to C10 alkyl group, or a combination thereof, and X¹ to X⁸ are each independently a single bond, —O—, —C(═O)—, —(CO)O—, —C(═O)NH—, or a combination thereof: 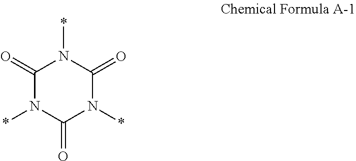
wherein, in Chemical Formula A-1, * is a linking point.

3. The resist underlayer composition as claimed in claim 1, wherein R³ to R⁶ in Chemical Formula 4 are each independently hydrogen, deuterium, a substituted or unsubstituted C1 to C10 alkyl group, or a combination thereof.

4. The resist underlayer composition as claimed in claim 1, wherein the polymer further comprises a structural unit represented by Chemical Formula 5, a structural unit represented by Chemical Formula 6, a structural unit represented by Chemical Formula 7, or a combination thereof: 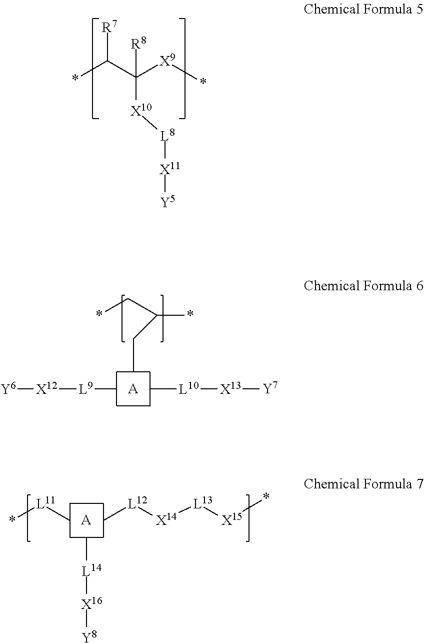
wherein, in Chemical Formula 5 to Chemical Formula 7,
R⁷ and R⁸ are each independently hydrogen, deuterium, a hydroxy group, a halogen atom, a substituted or unsubstituted C1 to C20 alkyl group, substituted or unsubstituted C2 to C20 alkenyl group, a substituted or unsubstituted C2 to C20 alkynyl group, or a combination thereof,
A is a heterocyclic group including a nitrogen atom in a ring,
L⁸ to L¹⁴ are each independently a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C3 to C20 heteroarylene group, or a combination thereof,
X⁹ to X¹⁶ are each independently a single bond, —O—, —S—, —S(═O)—, —S(═O)₂—, —C(═O)—, —(CO)O—, —O(CO)O—, —C(═O)NH—, —NR^{b}— (wherein, R^{b} is hydrogen, deuterium, or a C1 to C10 alkyl group), or a combination thereof,
Y⁵ to Y⁸ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a combination thereof, and
* is a linking point.

5. The resist underlayer composition as claimed in claim 4, wherein A of Chemical Formula 6 and Chemical Formula 7 is represented by one or more selected from Chemical Formula A-1 to Chemical Formula A-4: 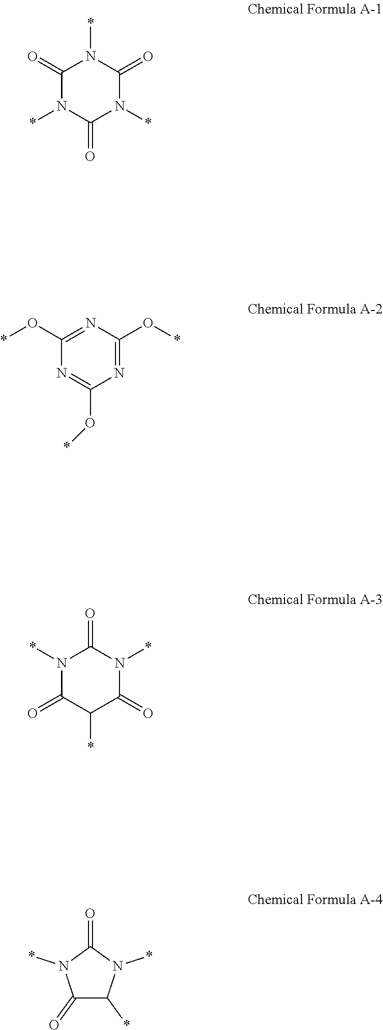
wherein, in Chemical Formula A-1 to Chemical Formula A-4 * is a linking point.

6. The resist underlayer composition as claimed in claim 4, wherein R⁷ and R⁸ are each independently hydrogen, deuterium, a substituted or unsubstituted C1 to C10 alkyl group, or a combination thereof,
L⁸ to L¹⁴ are each independently a single bond, a substituted or unsubstituted C1 to C10 alkylene group, a substituted or unsubstituted C1 to C10 heteroalkylene group, or a combination thereof,
X⁹ to X¹⁶ are each independently a single bond, —O—, —S—, —C(═O)—, —(CO)O—, or a combination thereof, and
Y⁵ to Y⁸ are each independently a hydroxy group, a substituted or unsubstituted C1 to C10 alkyl group, a substituted or unsubstituted C2 to C10 alkenyl group, a substituted or unsubstituted C2 to C20 heterocycloalkyl group, or a combination thereof.

7. The resist underlayer composition as claimed in claim 1, wherein the structural unit represented by Chemical Formula 1 is represented by one or more selected from Chemical Formula 1-1 to Chemical Formula 1-5:

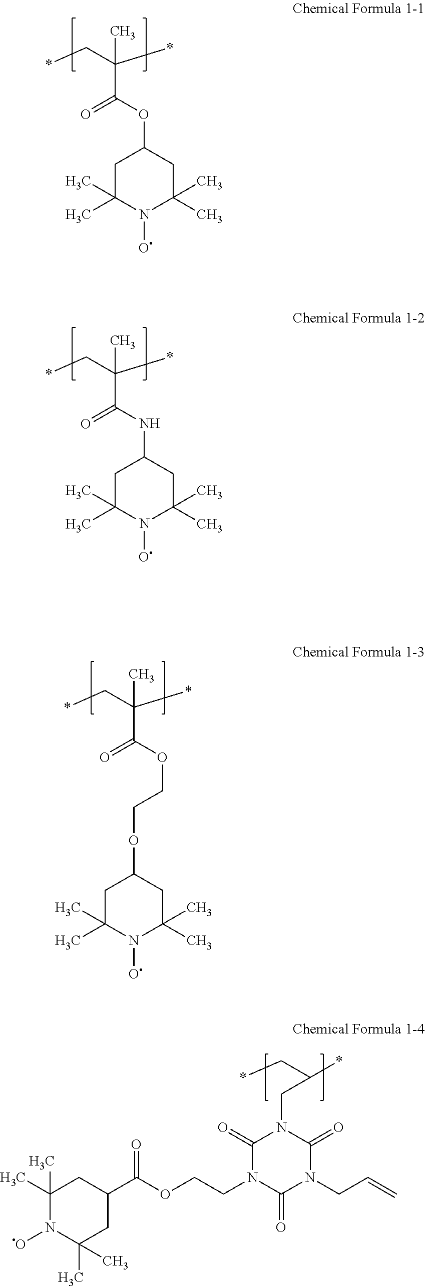

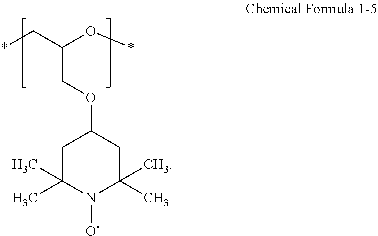

8. The resist underlayer composition as claimed in claim 1, wherein the polymer comprises about 5 mol % to about 50 mol % of at least one structural unit represented by Chemical Formula 1 to Chemical Formula 3, based on the number of moles of total structural units.

9. The resist underlayer composition as claimed in claim 1, wherein a weight average molecular weight of the polymer is about 1,000 g/mol to about 300,000 g/mol.

10. The resist underlayer composition as claimed in claim 1, wherein the polymer is included in an amount of about 0.1 wt % to about 50 wt % based on a total weight of the resist underlayer composition.

11. The resist underlayer composition as claimed in claim 1, wherein the resist underlayer composition further comprises one or more additional polymers selected from an acryl-based resin, an epoxy-based resin, a novolac-based resin, a glycoluril-based resin, and a melamine-based resin.

12. The resist underlayer composition as claimed in claim 1, wherein the resist underlayer composition further comprises an additive comprising a surfactant, a thermal acid generator, a photoacid generator, a plasticizer, or a combination thereof.

13. A method of forming a pattern, comprising:
forming a film to be etched on a substrate,
coating the resist underlayer composition as claimed in claim 1 on the film to be etched to form a resist underlayer,
forming a photoresist pattern on the resist underlayer, and
etching the resist underlayer and the film to be etched sequentially using the photoresist pattern as an etch mask.
